(19) United States
(12) Patent Application Publication
(10) Pub. No.: US 2024/0222389 A1
(43) Pub. Date: Jul. 4, 2024

(54) THIN FILM TRANSISTOR, DISPLAY PANEL, AND METHOD OF MANUFACTURING THE DISPLAY PANEL

(71) Applicant: Guangzhou China Star Optoelectronics Semiconductor Display Technology Co., LTd., Guangzhou (CN)

(72) Inventor: Wen SHI, Guangzhou (CN)

(73) Assignee: Guangzhou China Star Optoelectronics Semiconductor Display Technology Co., LTd., Guangzhou (CN)

(21) Appl. No.: 18/510,360

(22) Filed: Nov. 15, 2023

(30) Foreign Application Priority Data
Dec. 30, 2022 (CN) 202211734956.5

(51) Int. Cl. H01L 27/12

(52) U.S. Cl. CPC H01L 27/124; H01L 27/1259

(57) ABSTRACT

The present disclosure relates to a thin film transistor, a display, and a method of manufacturing the display panel. The thin film transistor comprises a substrate; a light shielding layer, a buffer layer, a semiconductor layer, a gate insulating layer, a gate layer, and a source-drain metal layer are arranged in sequence on the substrate, wherein the source-drain metal layer is in contact with the semiconductor layer; a planarization layer covering the source-drain metal layer; a protective layer disposed on the planarization layer; a first metal layer disposed on the protective layer, wherein the first metal layer is in contact with the source-drain metal layer; and a pixel electrode layer disposed on the first metal layer.

This disclosure claims priority to Chinese Patent Disclosure No. 202211734956.5, filed in the China National Intellectual Property Administration on Dec. 30, 2022, which is incorporated herein by reference in its entirety.

### TECHNICAL FIELD

The present disclosure relates to a field of display, and in particular to a thin film transistor, a display panel, and a method of manufacturing the display panel.

### BACKGROUND

Glass-based Mini/Micro-Light Emitting Diode (MLED) direct-view display products have broad disclosure in fields such as conference rooms, home theaters, exhibition halls and outdoor displays due to their advantages of high color gamut, high brightness, and infinite splicing.

Glass-based MLED can be divided into two types, narrow bonding and back bonding, based on bonding method. For general small pitch glass-based MLED, adopting a relatively simple and narrow bonding technology has advantages in terms of cost, yield and other aspects.

However, due to the size limitation of seam of the narrow bonding, nowadays, source fanout lines of glass-based MLED light panels needs to be disposed within the display area (AA) (if disposed outside the display area (AA), spacing between LEDs at the seam will be too large), which leads to the overlap of fanout lines with the data lines and sense lines within the display area (AA). A number of source fanout lines across different sense lines varies. As is shown in FIG. 1, according to a film structure of a top gate TFT, source chip (IC) lines usually adopt a light shielding (LS) layer, and the LS layer is horizontally connected with data lines, VDD lines, VSS lines, or sense lines through via holes after coming out of the source IC. The data lines, VDD lines, VSS lines, or sense lines usually adopt metal layers. Because of the presence of capacitance between crossed lines, the capacitance on different sense lines varies. In the processes of detection and compensation, due to the inconsistent capacitances on the different sense lines, there is an issue of inaccurate detection, resulting in uneven LED display. Therefore, the existing technology needs improvement.

### SUMMARY

The present disclosure provides a thin film transistor, a display panel, and a method of manufacturing the display panel that avoid problems of detection compensation and uneven display caused by capacitance difference formed by cross-line coupling between source fanout lines and lines such as data lines and induction lines.

According to an aspect, the present disclosure provides a thin film transistor, comprising:
a substrate;
a light shielding layer, a buffer layer, a semiconductor layer, a gate insulating layer, a gate layer, and a source-drain metal layer are arranged in sequence on the substrate, wherein the source-drain metal layer is in contact with the semiconductor layer;
a planarization layer covering the source-drain metal layer;
a protective layer disposed on the planarization layer;
a first metal layer disposed on the protective layer, wherein the first metal layer is in contact with the source-drain metal layer; and
a pixel electrode layer disposed on the first metal layer.

In a possible implementation embodiment of the present disclosure, the substrate is further provided with an intermediate definition layer covering the buffer layer, the semiconductor layer, the gate insulating layer and the gate layer.

In a possible implementation embodiment of the present disclosure, the intermediate definition layer is provided with a plurality of first contact holes, the plurality of first contact holes are configured to expose the semiconductor layer, and the source-drain metal layer is in contact with the semiconductor layer through the plurality of first contact holes.

In a possible implementation embodiment of the present disclosure, the planarization layer and the protective layer are jointly provided with a plurality of second contact holes, the plurality of second contact holes are configured to expose the source-drain metal layer, and the first metal layer is in contact with the source-drain metal layer through the plurality of second contact holes.

In a possible implementation embodiment of the present disclosure, a material of the buffer layer, a material of the gate insulating layer, and a material of the protective layer are independently selected from an inorganic material, an organic material or combinations thereof, wherein the inorganic material is selected from silicon oxide, silicon nitride, silicon oxynitride or combinations thereof.

In a possible implementation embodiment of the present disclosure, the gate layer is disposed on the gate insulating layer and overlapped with the gate insulating layer.

In a possible implementation embodiment of the present disclosure, a material of the light shielding layer is a colored mono-metal oxide or a composite metal oxide.

In a possible implementation embodiment of the present disclosure, a material of the semiconductor layer is selected from a metal oxide semiconductor, amorphous silicon, monocrystalline silicon, polysilicon or combinations thereof, the metal oxide semiconductor is selected from indium gallium zinc oxide, tin oxide, indium zinc oxide, hafnium indium zinc oxide, indium gallium oxide, cadmium oxide, germanium oxide, nickel cobalt oxide or combinations thereof.

According to another aspect, the present disclosure further provides a display panel comprising a thin film transistor, wherein the thin film transistor comprising:
a substrate;
a light shielding layer, a buffer layer, a semiconductor layer, a gate insulating layer, a gate layer, and a source-drain metal layer are arranged in sequence on the substrate, wherein the source-drain metal layer is in contact with the semiconductor layer;
a planarization layer covering the source-drain metal layer;
a protective layer disposed on the planarization layer;
a first metal layer disposed on the protective layer, wherein the first metal layer is in contact with the source-drain metal layer; and
a pixel electrode layer disposed on the first metal layer;
wherein the display panel further comprises a second metal layer integrally formed with the gate layer and a third metal layer integrally formed with the source-drain metal layer; and
wherein the second metal layer comprises a plurality of scan lines, and the third metal layer comprises a plurality of data lines insulated from the plurality of scan lines.

In a possible implementation embodiment of the present disclosure, the substrate is further provided with an intermediate definition layer covering the buffer layer, the semiconductor layer, the gate insulating layer and the gate layer.

In a possible implementation embodiment of the present disclosure, the intermediate definition layer is provided with a plurality of first contact holes, the plurality of first contact holes are configured to expose the semiconductor layer, and the source-drain metal layer is in contact with the semiconductor layer through the plurality of first contact holes.

In a possible implementation embodiment of the present disclosure, the planarization layer and the protective layer are jointly provided with a plurality of second contact holes, the plurality of second contact holes are configured to expose the source-drain metal layer, and the first metal layer is in contact with the source-drain metal layer through the plurality of second contact holes.

In a possible implementation embodiment of the present disclosure, a material of the buffer layer, a material of the gate insulating layer, and a material of the protective layer are independently selected from an inorganic material, an organic material or combinations thereof, wherein the inorganic material is selected from silicon oxide, silicon nitride, silicon oxynitride or combinations thereof.

In a possible implementation embodiment of the present disclosure, a material of the semiconductor layer is selected from a metal oxide semiconductor, amorphous silicon, monocrystalline silicon, polysilicon or combinations thereof, the metal oxide semiconductor is selected from indium gallium zinc oxide, tin oxide, indium zinc oxide, hafnium indium zinc oxide, indium gallium oxide, cadmium oxide, germanium oxide, nickel cobalt oxide or combinations thereof.

In a possible implementation embodiment of the present disclosure, the third metal layer further comprises a plurality of power supply lines and a plurality of induction lines.

In a possible implementation embodiment of the present disclosure, a material of the first metal layer, a material of the second metal layer, a material of the third metal layer, a material of the plurality of scan lines, a material of the plurality of data lines, a material of the plurality of power lines, a material of the plurality of induction lines, a material of the gate layer, and a material of the source-drain metal layer are independently selected from molybdenum, titanium, aluminum, copper or combinations thereof.

According to another aspect, the present disclosure further provides a method of manufacturing a display panel, comprising:
providing a substrate;
sequentially preparing a light shielding layer, a buffer layer, a semiconductor layer, a gate insulating layer, a gate layer, and a source-drain metal layer in contact with the semiconductor layer on the substrate;
preparing a planarization layer covering the source-drain metal layer on the substrate;
preparing a protective layer on the planarization layer; and
preparing a first metal layer in contact with the source-drain metal layer on the protective layer, and preparing a pixel electrode layer on the first metal layer.

In a possible implementation embodiment of the present disclosure, preparing a first metal layer in contact with the source-drain metal layer on the protective layer, and preparing a pixel electrode layer on the first metal layer, comprise:
depositing a metal layer on the protective layer;
depositing a pixel electrode material layer on the metal layer; and
simultaneously patterning the metal layer and the pixel electrode material layer to form the first metal layer and the pixel electrode layer.

In a possible implementation embodiment of the present disclosure, wherein after preparing a protective layer on the planarization layer, the method further comprises: patterning the protective layer and the planarization layer, to form a plurality of second contact holes exposing the source-drain metal layer on the planarization layer and the protective layer.

In a possible implementation embodiment of the present disclosure, wherein sequentially preparing a light shielding layer, a buffer layer, a semiconductor layer, a gate insulating layer, a gate layer, and a source-drain metal layer in contact with the semiconductor layer on the substrate comprise:
preparing a metal layer on the substrate, and photolithographing the metal layer to form a light shielding layer;
depositing a layer of buffer material as a buffer layer on the light shielding layer;
depositing a layer of semiconductor material, and exposing and developing the layer of semiconductor material to form a semiconductor layer;
depositing a layer of gate insulating material as a gate insulating layer on the semiconductor layer;
depositing a metal layer and etching the metal layer to form the grid layer, and dry etching the grid insulating layer;
depositing a layer of an inorganic material or an organic material as an intermediate definition layer;
forming a plurality of holes on the middle definition layer after the middle definition layer is formed, and forming a plurality of holes on the buffer layer, to form a plurality of first contact holes exposing the semiconductor layer; and
preparing a third metal layer on the intermediate definition layer and in the plurality of first contact holes to form a source-drain metal layer.

In the present disclosure, a first metal layer in contact with the source-drain metal layer is disposed on the protective layer, and a pixel electrode layer is disposed on the first metal layer, thereby the first metal layer can be used as source fanout lines. By incorporating a planarization layer between the first metal layer and the source-drain metal layer, and reducing the capacitance difference generated by the cross-line coupling between the source fanout lines and lines such as the plurality of data lines and the plurality of induction lines by the incorporated planarization layer, the problems of detection compensation and uneven display have been resolved.

### BRIEF DESCRIPTION OF FIGURES

In order to clearly explain the technical solutions in the embodiments of the present disclosure, the following context will briefly introduce the drawings required in the description of the embodiments. It is clear that the drawings in the following description are only some embodiments of the present disclosure. For those skilled in the art, without paying any creative effort, other drawings can be obtained based on these drawings.

FIG. 1 is a schematic structural diagram of a thin film transistor according to an embodiment of the present disclosure;

FIG. 2 is a schematic structural diagram of a processing structure in a preparation process of a method of manufacturing a display panel according to an embodiment of the present disclosure;

FIG. 3 is a schematic structural diagram of a processing structure in a preparation process of a method of manufacturing a display panel according to an embodiment of the present disclosure;

FIG. 4 is a schematic structural diagram of a processing structure in a preparation process of a method of manufacturing a display panel according to an embodiment of the present disclosure;

FIG. 5 is a schematic structural diagram of a processing structure in a preparation process of a method of manufacturing a display panel according to an embodiment of the present disclosure;

FIG. 6 is a schematic structural diagram of a processing structure in a preparation process of a method of manufacturing a display panel according to an embodiment of the present disclosure;

FIG. 7 is a schematic structural diagram of a processing structure in a preparation process of a method of manufacturing a display panel according to an embodiment of the present disclosure;

FIG. 8 is a schematic structural diagram of a processing structure in a preparation process of a method of manufacturing a display panel according to an embodiment of the present disclosure;

FIG. 9 is a schematic structural diagram of a processing structure in a preparation process of a method of manufacturing a display panel according to an embodiment of the present disclosure;

FIG. 10 is a schematic structural diagram of a processing structure in a preparation process of a method of manufacturing a display panel according to an embodiment of the present disclosure;

FIG. 11 is a schematic structural diagram of a processing structure in a preparation process of a method of manufacturing a display panel according to an embodiment of the present disclosure;

FIG. 12 is a flowchart showing a method of manufacturing a display panel according to an embodiment of the present disclosure.

### EMBODIMENTS OF THE PRESENT DISCLOSURE

Technical solutions in embodiments of the present disclosure will be clearly and completely described below in conjunction with drawings in the embodiments of the present disclosure. Obviously, the described embodiments are only some embodiments of the present disclosure, and not limited to the embodiments. Based on the embodiments in the present disclosure, all other embodiments obtained by those skilled in the art without creative effort fall within the protection scope of the present disclosure.

In the description of the present disclosure, it is to be understood that the terms “center,” “longitudinal,” “transverse,” “length,” “width,” “thickness,” “up,” “down,” “front,” “back,” “left,” “right,” “vertical,” “horizontal,” “top,” “bottom,” “inside,” “outside,” and the like indicate orientations or positional relationships based on those shown in the drawings and are intended only for the ease of describing and simplifying the description, rather than indicating or implying that the device or element referred to must have a specific orientation, or be constructed and operated in a particular orientation. Therefore the terms cannot be construed as limiting the present disclosure. Furthermore, the terms “first” and “second” are used for the purposes of description only and cannot be understood as indicating or implying relative importance or implying the number of technical features indicated. Thus, features defined as “first,” “second,” may explicitly or implicitly include one or more of the features. In the description of the present disclosure, “multiple/a plurality of” means two or more, unless expressly specified otherwise.

In the present disclosure, the term “exemplary”, “embodiment” is used to mean “serving as an example, illustration or illustration”. Any embodiment in the present disclosure described as “exemplary” is not necessarily construed as being more preferred or advantageous than other embodiments. The following description is given to enable any of those skilled in the art to practice and use the present disclosure. In the following description, the details are listed for the purpose of explanation. It should be understood that one of those ordinary skilled in the art will recognize that the present disclosure may be practiced without the use of these specific details. In other embodiments, known or commonly used structures and processes will not be elaborated in detail to avoid unnecessary redundancy that obscure the description of the present disclosure. For ordinary technical personnel in this field, it is clear that known or commonly used structures or features are included within the scope of this disclosure. Accordingly, the present disclosure is not intended to be limited to the embodiments shown but is consistent with the broadest scope consistent with the principles and features disclosed herein.

An embodiment of the present disclosure provides a thin film transistor, a display, and a method of manufacturing the display panel, which are described in detail below.

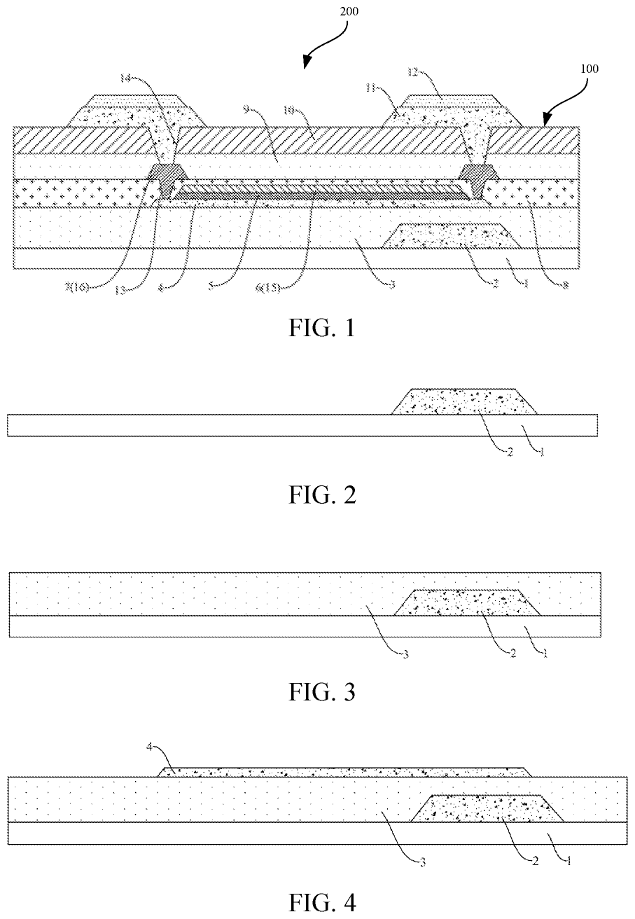

As is shown in FIG. 1, the present disclosure provides a thin film transistor 100 including a substrate 1. A light shielding layer 2, a buffer layer 3, a semiconductor layer 4, a gate insulating layer 5, a gate layer 6 and a source-drain metal layer 7 are arranged in sequence on the substrate 1. The source-drain metal layer 7 is in contact with the semiconductor layer 4.

The substrate 1 is further provided with a planarization layer 9 covering the source-drain metal layer 4 and a protective layer 10 disposed on the planarization layer 9. A first metal layer 11 in contact with the source-drain metal layer 7 is disposed on the protective layer 10, and a pixel electrode layer 12 is disposed on the first metal layer 11.

In the present disclosure, the first metal layer 11 in contact with the source-drain metal layer 7 is disposed on the protective layer 10, and the pixel electrode layer 12 is disposed on the first metal layer 11, thereby the first metal layer 11 can be used as source fanout lines. Since there is a planarization layer 9 between the first metal layer 11 and the source-drain metal layer 7, a capacitance difference generated by the cross-line coupling between the source fanout lines and lines such as a plurality of data lines and a plurality of induction lines can be weakened through the planarization layer 9, thus solving the problems of detection compensation and uneven display.

The substrate 1 may be a glass substrate or a plastic substrate. In an embodiment of the present disclosure, specifically, the substrate 1 may be a transparent substrate or an opaque/reflective substrate. A material of the transparent substrate may be selected from glass, quartz, organic polymer, other suitable materials or combinations thereof. A material of the opaque/reflective substrate may be selected from conductive material, metal, wafer, ceramic, other suitable materials or combinations thereof. It should be noted that, if the material of the substrate 1 is selected to be the conductive material, an insulating layer (not shown) is needed to be formed on the substrate 1 before components of the thin film transistor 100 are disposed on the substrate 1, so as to avoid a problem of short circuit between the substrate 1 and the components of the thin film transistor 100. The substrate 1 may be a rigid substrate or a flexible substrate in terms of mechanical characteristics. A material of the rigid substrate may be selected from glass, quartz, conductive material, metal, wafer, ceramic, other suitable materials or combinations thereof, and the embodiment of the present disclosure is not specifically limited thereto. A material of the flexible substrate may be selected from ultra-thin glass, organic polymer (such as plastic), other suitable materials or combinations thereof, and the embodiments of the present disclosure are not specifically limited thereto.

The light shielding layer 2 is disposed on a side of the substrate 1. In an embodiment of the present disclosure, a material of the light shielding layer 2 may be a colored mono-metal oxide or a composite metal oxide, for example, a nonferrous metal oxide such as chromium oxide and titanium suboxide and composite oxides thereof. In an embodiment of the present disclosure, when the material of the light shielding layer 2 is the colored mono-metal oxide or the composite metal oxide, the light shielding layer 2 may be formed on the substrate 1 by electron beam evaporation, sputtering or the like. Wherein, the disclosure does not impose specific limitations on the materials of the light shielding layer 2.

On the substrate 1, the buffer layer 3 covering the light shielding layer 2 is disposed between the light shielding layer 2 and the semiconductor layer 4. In an embodiment of the present disclosure, the buffer layer 3 is configured to buffer the stress experienced by the array substrate 1 during the preparation of the thin film transistor 100, so as to avoid damage or rupture of the substrate 1. A material of the buffer layer 3 may be a buffer material. The buffer material may be selected from an inorganic material, an organic material or combinations thereof. The inorganic material may be selected from silicon oxide, silicon nitride, silicon oxynitride or combinations thereof. Wherein, the disclosure does not impose specific limitations on the materials of the buffer layer 3.

The semiconductor layer 4 is disposed on a side of the substrate 1 where the light shielding layer 2 is located. The semiconductor layer 4 is an active layer of the thin film transistor 100. In an embodiment of the present disclosure, a material of the semiconductor layer 4 may be a semiconductor material. The semiconductor material may be selected from a metal oxide semiconductor, amorphous silicon, monocrystalline silicon, polysilicon or combinations thereof. The metal oxide semiconductor may be selected from indium gallium zinc oxide (IGZO), tin oxide (ZnO), indium zinc oxide (IZO), hafnium indium zinc oxide (HIZO), indium gallium oxide (IGO), cadmium oxide, germanium oxide (2CdO·GeO₂), nickel cobalt oxide (NiCo₂O₄) or combinations thereof. Wherein, the disclosure does not impose specific limitations on the materials of the semiconductor layer 4.

The gate insulating layer 5 is disposed on a side of the substrate 1 where the light shielding layer 2 is located. In an embodiment of the present disclosure, a material of the gate insulating layer 5 may be a gate insulating material. The gate insulating material may be selected from an inorganic material, an organic material or combinations thereof. The inorganic material may be selected from silicon oxide, silicon nitride, silicon oxynitride or combinations thereof. Wherein, the disclosure does not impose specific limitations on the materials of the gate insulating layer 5.

The gate layer 6 is disposed on a side of the substrate 1 where the light shielding layer 2 is located. The gate layer 6 is disposed on the gate insulating layer 5 and overlapped with the gate insulating layer 5. In an embodiment of the present disclosure, a material of the gate layer 6 may be a metallic material or other conductive materials. For example, the material of the gate layer 6 may be an alloy, a nitride of a metallic material, an oxide of a metallic material, a nitrogen oxide of a metallic material, or a combination thereof. Wherein, the disclosure does not impose specific limitations on the materials of the gate layer 6.

The source-drain metal layer 7 includes a source metal layer configured to disposed a source electrode and a drain metal layer configured to disposed a drain electrode. The source metal layer and the drain metal layer respectively correspond to a source electrode and a drain electrode disposed at intervals at two ends of the semiconductor layer 3. In an embodiment of the present disclosure, a material of the source-drain metal layer 7 may be a metallic material or other conductive materials. For example, the material of the source-drain metal layer 7 may be an alloy, a nitride of a metallic material, an oxide of a metallic material, a nitrogen oxide of a metallic material, or a combination thereof. Wherein, the disclosure does not impose specific limitations on the materials of the source-drain metal layer 7.

The substrate is also provided with an intermediate definition layer 8 covering all of the buffer layer 2, the semiconductor layer 4, the gate insulating layer 5 and the gate layer 6. The intermediate definition layer 8 is configured to isolate the source-drain metal layer 7 and the gate layer 6 to achieve interlayer insulation between the source-drain metal layer 7 and the gate layer 6. A material of the intermediate definition layer 8 may be selected from an inorganic material, an organic material or combinations thereof. The inorganic material may be selected from silicon oxide, silicon nitride, silicon oxynitride or combinations thereof. Wherein, the disclosure does not impose specific limitations on the materials of the intermediate definition layer 8.

The planarization layer 9 covers the source-drain metal layer 7 for improving the flatness of the thin film transistor 100 and making the surface of the thin film transistor 100 more flat. A material of the planarization layer 9 may be an organic material, specifically a polyimide (PI), or other materials. Wherein, the disclosure does not impose specific limitations on the materials of the planarization layer 9.

The protective layer 10 is disposed on the planarization layer 9. A material of the protective layer 10 may be a protective material. The protective material may be selected from an inorganic material, an organic material or combinations thereof. The inorganic material may be selected from silicon oxide, silicon nitride, silicon oxynitride or combinations thereof. Wherein, the disclosure does not impose specific limitations on the materials of the protective layer 10.

The first metal layer 11 is disposed on the protective layer 10, and the first metal layer 11 is in contact with the source-drain metal layer 7. In an embodiment of the present disclosure, the first metal layer 11 is used as the source fanout lines of a display panel. Because the intermediate definition layer 8, the planarization layer 9 and the protective layer 10 are arranged between the first metal layer 11 and the source-drain metal layer 7, and the planarization layer 9 has a thickness, the capacitance between the first metal layer 11 and a third metal layer 16 can be weakened, and the detection compensation and uneven display problems caused by the capacitance difference generated by the cross-line coupling between the source fanout lines (using the first metal layer 11) and lines such as the plurality of data lines and the plurality of induction lines (using the third metal layer 16) can be avoided.

The pixel electrode layer 12 is disposed on the first metal layer 11. A material of the pixel electrode layer 12 is a pixel electrode material. The pixel electrode material may be selected from indium tin oxide, which is not specifically limited in embodiments of the present disclosure. Wherein, the disclosure does not impose specific limitations on the materials of the pixel electrode layer 12.

In some embodiments of the present disclosure, the intermediate definition layer 8 is provided with a plurality of first contact holes 13, which are configured to expose the semiconductor layer 4. The source-drain metal layer 7 is in contact with the semiconductor layer 4 through the plurality of first contact holes 13.

In some embodiments of the present disclosure, the planarization layer 9 and the protective layer 10 are jointly provided with a plurality of second contact holes 14. The plurality of second contact holes 14 are configured to expose the source-drain metal layer 7. The first metal layer 11 is in contact with the source-drain metal layer 7 through the plurality of second contact holes 14.

In the present disclosure, substrate 1, the light shielding layer 2, the buffer layer 3, the intermediate definition layer 8, the semiconductor layer 4, the gate insulating layer 5, the gate layer 6, the source-drain metal layer 7, the planarization layer 9, the protective layer 10, the first metal layer 11 and the pixel electrode layer 12 together constitute a structure of the thin film transistor 100.

According to another aspect, the present disclosure further provides a display panel 200 including the thin film transistor 100. The display panel 200 further includes a second metal layer 15 integrally formed with the gate layer 6 and a third metal layer 16 integrally formed with the source-drain metal layer 7. The second metal layer 15 includes a plurality of scan lines, and the third metal layer 16 includes a plurality of data lines insulated from the plurality of scan lines.

In some embodiments of the present disclosure, the third metal layer 16 further includes a plurality of power supply lines and a plurality of induction lines. The plurality of power supply lines are configured to lay out physical lines such as VDD lines and VSS lines, which can save pixel layout space.

In some embodiments of the present disclosure, a material of the first metal layer 11, a material of the second metal layer 15, a material of the third metal layer 16, a material of the plurality of scan lines, a material of the plurality of data lines, a material of the plurality of power lines, a material of the plurality of induction lines, a material of the gate layer 6, and a material of the source-drain metal layer 7 are independently selected from molybdenum, titanium, aluminum, copper or combinations thereof, which are stacked in layers if more than one materials.

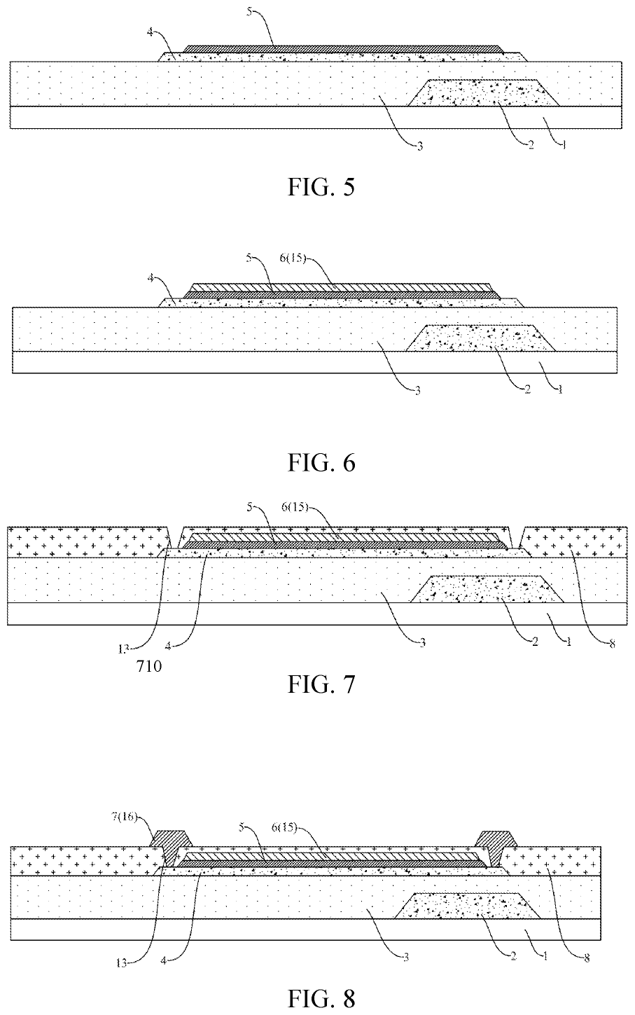

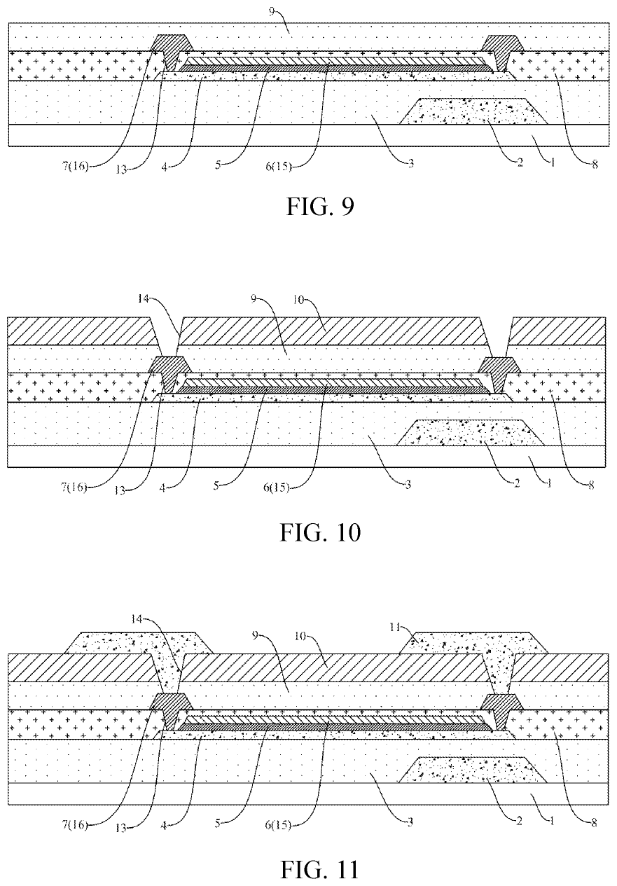

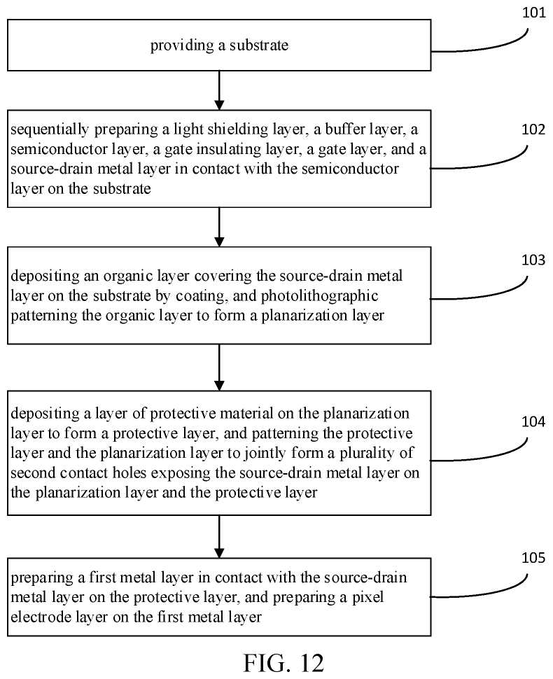

According to another aspect, referring to FIG. 1 to FIG. 12, the present disclosure further provides a method of manufacturing a display panel, including the following steps:
S101, providing a substrate 1;
S102, sequentially preparing a light shielding layer 2, a buffer layer 3, a semiconductor layer 4, a gate insulating layer 5, a gate layer 6, and a source-drain metal layer 7 in contact with the semiconductor layer 4 on the substrate 1;
S103, depositing an organic layer covering the source-drain metal layer 7 on the substrate by coating, and photolithographic patterning the organic layer to form a planarization layer 9;
S104, depositing a layer of protective material on the planarization layer 9 to form a protective layer 10, and patterning the protective layer 10 and the planarization layer 9 to jointly form a plurality of second contact holes 14 exposing the source-drain metal layer 7 on the planarization layer 9 and the protective layer 10; and
S105, preparing a first metal layer 11 in contact with the source-drain metal layer 7 on the protective layer 10, and preparing a pixel electrode layer 12 on the first metal layer 11.

It should be noted that, in embodiments of the present disclosure, a method of depositing may be Chemical Vapor Deposition (CVD), Physical Vapor Deposition (PVD).

In an embodiment of the present disclosure, the $102 step specifically includes:
S1021, preparing a metal layer on the substrate 1, and photolithographing the metal layer to form a light shielding layer 2;
S1022, depositing a layer of a buffer material as a buffer layer 3 on the light shielding layer 2;
S1023, depositing a layer of a semiconductor material, and exposing and developing the layer of semiconductor material to form a semiconductor layer 4;
S1024, depositing a layer of gate insulating material as a gate insulating layer 5 on the semiconductor layer 4;
S1025, depositing a metal layer and etching the metal layer to form the grid layer 6, and dry etching the grid insulating layer 5 by using a same mask with the etching of the metal layer;

S1026, depositing a layer of an inorganic material or an organic material as an intermediate definition layer 8;
S1027, forming a plurality of holes on the middle definition layer 8 after the middle definition layer 8 is formed, and forming a plurality of holes on the buffer layer 3, to form a plurality of first contact holes 13 exposing the semiconductor layer 4; and
S1028, preparing a third metal layer 16 on the intermediate definition layer 8 and in the plurality of first contact holes 13 to form a source-drain metal layer 7.

In at least one specifically embodiment of the present disclosure, the S102 step specifically includes:
S1021, preparing a metal layer on the substrate 1, and photolithographing the metal layer to form a light shielding layer 2;
S1022, depositing a layer of SiOx as a buffer layer 3 on the light shielding layer 2;
S1023, depositing a layer of indium gallium zinc oxide (IGZO) by means of Physical Vapor Deposition (PVD), and exposing and developing the layer of indium gallium zinc oxide (IGZO) to form a semiconductor layer 4;
S1024, depositing a layer of SiOₓ as a gate insulating layer 5 by PVD on the semiconductor layer 4;
S1025, depositing a metal layer by PVD and etching the metal layer to form the grid layer 6, and dry etching the grid insulating layer 5 by using a same mask with the etching of the metal layer;
S1026, depositing a layer of SiOₓ as an intermediate definition layer 8 by Chemical Vapor Deposition (CVD);
S1027, forming a plurality of holes on the middle definition layer 8 after the middle definition layer 8 is formed, and forming a plurality of holes on the buffer layer 3, to form a plurality of first contact holes 13 exposing the semiconductor layer 4; and
S1028, preparing a third metal layer 16, on the intermediate definition layer 8 and in the plurality of first contact holes 13 to form the source-drain metal layer 7.

In some embodiments of the present disclosure, the steps of preparing a first metal layer 11 in contact with the source-drain metal layer 7 on the protective layer 10, and preparing a pixel electrode layer 12 on the first metal layer 11, include:
S1051, depositing a metal layer on the protective layer 10;
in which a metal layer is deposited on the protective layer 10, and the metal layer is used as the first metal layer 11; and in an embodiment of the present disclosure, the first metal layer 11 is in contact with the source-drain metal layer 7 through the plurality of the second contact holes 14; and
S1052, depositing a pixel electrode material layer on the metal layer,
in which a pixel electrode material is deposited on the first metal layer 11, and the pixel electrode material is used as the pixel electrode layer 12;
S1053, simultaneously patterning the metal layer and the pixel electrode material layer to form a first metal layer 11 and a pixel electrode layer 12.

In the embodiment, because the metal layer is directly laid under the indium tin oxide layer, and the metal layer and the indium tin oxide layer are patterned simultaneously, the mask cost is not increased. Furthermore, because the indium tin oxide layer is disposed on the first metal layer 11, the risk of metal scratching in the subsequent process can be reduced.

The thin film transistor, the display, and the method of manufacturing the display panel according to embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

What is claimed is:

1. A thin film transistor, comprising:
a substrate;
a light shielding layer, a buffer layer, a semiconductor layer, a gate insulating layer, a gate layer, and a source-drain metal layer are arranged in sequence on the substrate, wherein the source-drain metal layer is in contact with the semiconductor layer;
a planarization layer covering the source-drain metal layer;
a protective layer disposed on the planarization layer;
a first metal layer disposed on the protective layer, wherein the first metal layer is in contact with the source-drain metal layer; and
a pixel electrode layer disposed on the first metal layer.

2. The thin film transistor according to claim 1, wherein the substrate is further provided with an intermediate definition layer covering the buffer layer, the semiconductor layer, the gate insulating layer and the gate layer.

3. The thin film transistor according to claim 2, wherein the intermediate definition layer is provided with a plurality of first contact holes, the plurality of first contact holes are configured to expose the semiconductor layer, and the source-drain metal layer is in contact with the semiconductor layer through the plurality of first contact holes.

4. The thin film transistor according to claim 1, wherein the planarization layer and the protective layer are jointly provided with a plurality of second contact holes, the plurality of second contact holes are configured to expose the source-drain metal layer, and the first metal layer is in contact with the source-drain metal layer through the plurality of second contact holes.

5. The thin film transistor according to claim 1, wherein a material of the buffer layer, a material of the gate insulating layer, and a material of the protective layer are independently selected from an inorganic material, an organic material or combinations thereof, wherein the inorganic material is selected from silicon oxide, silicon nitride, silicon oxynitride or a combination thereof.

6. The thin film transistor according to claim 1, wherein the gate layer is disposed on the gate insulating layer and overlapped with the gate insulating layer.

7. The thin film transistor according to claim 1, wherein a material of the light shielding layer is a colored mono-metal oxide or a composite metal oxide.

8. The thin film transistor according to claim 1, wherein a material of the semiconductor layer is selected from a metal oxide semiconductor, amorphous silicon, monocrystalline silicon, polysilicon or combinations thereof, the metal oxide semiconductor is selected from indium gallium zinc oxide, tin oxide, indium zinc oxide, hafnium indium zinc oxide, indium gallium oxide, cadmium oxide, germanium oxide, nickel cobalt oxide or combinations thereof.

9. A display panel comprising a thin film transistor, wherein the thin film transistor comprising:
a substrate;
a light shielding layer, a buffer layer, a semiconductor layer, a gate insulating layer, a gate layer, and a source-drain metal layer are arranged in sequence on the substrate, wherein the source-drain metal layer is in contact with the semiconductor layer;
a planarization layer covering the source-drain metal layer;
a protective layer disposed on the planarization layer;
a first metal layer disposed on the protective layer, wherein the first metal layer is in contact with the source-drain metal layer; and
a pixel electrode layer disposed on the first metal layer;
wherein the display panel further comprises a second metal layer integrally formed with the gate layer and a third metal layer integrally formed with the source-drain metal layer; and
wherein the second metal layer comprises a plurality of scan lines, and the third metal layer comprises a plurality of data lines insulated from the plurality of scan lines.

10. The display panel according to claim 9, wherein the substrate is further provided with an intermediate definition layer covering the buffer layer, the semiconductor layer, the gate insulating layer and the gate layer.

11. The display panel according to claim 10, wherein the intermediate definition layer is provided with a plurality of first contact holes, the plurality of first contact holes are configured to expose the semiconductor layer, and the source-drain metal layer is in contact with the semiconductor layer through the plurality of first contact holes.

12. The display panel according to claim 9, wherein the planarization layer and the protective layer are jointly provided with a plurality of second contact holes, the plurality of second contact holes are configured to expose the source-drain metal layer, and the first metal layer is in contact with the source-drain metal layer through the plurality of second contact holes.

13. The display panel according to claim 9, wherein a material of the buffer layer, a material of the gate insulating layer, and a material of the protective layer are independently selected from an inorganic material, an organic material or combinations thereof, wherein the inorganic material is selected from silicon oxide, silicon nitride, silicon oxynitride or combinations thereof.

14. The display panel according to claim 9, wherein a material of the semiconductor layer is selected from a metal oxide semiconductor, amorphous silicon, monocrystalline silicon, polysilicon or combinations thereof, the metal oxide semiconductor is selected from indium gallium zinc oxide, tin oxide, indium zinc oxide, hafnium indium zinc oxide, indium gallium oxide, cadmium oxide, germanium oxide, nickel cobalt oxide or combinations thereof.

15. The display panel according to claim 9, wherein the third metal layer further comprises a plurality of power supply lines and a plurality of induction lines.

16. The display panel according to claim 9, wherein a material of the first metal layer, a material of the second metal layer, a material of the third metal layer, a material of the plurality of scan lines, a material of the plurality of data lines, a material of the plurality of power lines, a material of the plurality of induction lines, a material of the gate layer, and a material of the source-drain metal layer are independently selected from molybdenum, titanium, aluminum, copper or combinations thereof.

17. A method of manufacturing a display panel, comprising:
providing a substrate;
sequentially preparing a light shielding layer, a buffer layer, a semiconductor layer, a gate insulating layer, a gate layer, and a source-drain metal layer in contact with the semiconductor layer on the substrate;
preparing a planarization layer covering the source-drain metal layer on the substrate;
preparing a protective layer on the planarization layer; and
preparing a first metal layer in contact with the source-drain metal layer on the protective layer, and preparing a pixel electrode layer on the first metal layer.

18. The method according to claim 17, wherein preparing a first metal layer in contact with the source-drain metal layer on the protective layer, and preparing a pixel electrode layer on the first metal layer, comprise:
depositing a metal layer on the protective layer;
depositing a pixel electrode material layer on the metal layer; and
simultaneously patterning the metal layer and the pixel electrode material layer to form the first metal layer and the pixel electrode layer.

19. The method according to claim 17, wherein after preparing a protective layer on the planarization layer, the method further comprises: patterning the protective layer and the planarization layer to form a plurality of second contact holes exposing the source-drain metal layer on the planarization layer and the protective layer.

20. The method according to claim 17, wherein sequentially preparing a light shielding layer, a buffer layer, a semiconductor layer, a gate insulating layer, a gate layer, and a source-drain metal layer in contact with the semiconductor layer on the substrate comprise:
preparing a metal layer on the substrate, and photolithographing the metal layer to form a light shielding layer;
depositing a layer of buffer material as a buffer layer on the light shielding layer;
depositing a layer of semiconductor material, and exposing and developing the layer of semiconductor material to form a semiconductor layer;
depositing a layer of gate insulating material as a gate insulating layer on the semiconductor layer;
depositing a metal layer and etching the metal layer to form the grid layer, and dry etching the grid insulating layer;
depositing a layer of an inorganic material or an organic material as an intermediate definition layer,
forming a plurality of holes on the middle definition layer after the middle definition layer is formed, and forming a plurality of holes on the buffer layer, to form a plurality of first contact holes exposing the semiconductor layer, and
preparing a third metal layer on the intermediate definition layer and in the plurality of first contact holes to form a source-drain metal layer.
